(19) United States
(12) Patent Application Publication
(10) Pub. No.: US 2015/0051856 A1
(43) Pub. Date: Feb. 19, 2015

(54) METHOD FOR ESTIMATING VOLTAGE STABILITY

(71) Applicant: National Tsing Hua University, Hsinchu (TW)

(72) Inventors: Chia-Chi Chu, Hsinchu (TW); Jian-Hong Liu, Hsinchu (TW)

(73) Assignee: National Tsing Hua University, Hsinchu (TW)

(21) Appl. No.: 14/048,901

(22) Filed: Oct. 8, 2013

(30) Foreign Application Priority Data
Aug. 13, 2013 (TW) 102128991

(51) Int. Cl. G01R 27/02

(52) U.S. Cl. CPC G01R 27/02
USPC 702/65

(57) ABSTRACT

A method for estimating voltage stability, includes establishing a multi-port equivalent model and the measurement-based equivalent impedance; calculating the reactive power response factor through two consecutive samples from wide-area phasor measurement unit measurement; finding the mitigation factor; constructing the modified coupled single-port model with the modified impedance and voltage; and using the modified maximal loading parameter for voltage stability assessment.

### TECHNICAL FIELD

The present invention relates to an estimating method, more especially a method for estimating voltage stability.

### BACKGROUND

As the power system becomes more stressed and the penetration of intermittent renewable energies increases, voltage stability assessment (VSA) becomes a key concern for maintaining and enhancing the security of bulk power systems. One method to mitigate the voltage collapse problem requires an efficient real-time voltage stability monitoring system. In recent years, with wide deployments of synchronized Phasor Measurement Units (PMUs), developing a real-time voltage stability monitoring system based on PMU measurements has become a trend for wide-area VSA.

Two different approaches have been proposed to evaluate long-term voltage stability: model-based methods and measurement-based methods. In model-based approaches, accurate system parameters are required. By exploring advanced numerical techniques to avoid computing the singular system Jacobian at the collapse point, this class of methods can provide very accurate results. For example, continuation power flow methods (CPFLOW), direct methods, and optimal power flow methods, have been developed along this direction. One advantage of this model-based approach is that all physical constraints, such as generator's reactive power limits and thermal limits of transmission lines, can also be considered. However, the computational complexity of such model-based methods is complicated. Real-time applications are limited.

Due to the recent advance of PMU technologies, measurement-based methods have opened new perspectives for designing voltage stability monitoring system. In early work, measurements gathered at a single location are utilized for voltage stability assessment. The maximum power transfer theorem of the single-port model provides a theoretical foundation for voltage stability assessment of individual load bus. Various voltage stability indicators (VSIs) have been proposed with different physical interpretations. The advantage of this measurement-based approach is its computational simplicity. Consequently, this measurement-based approach is very suitable for real-time applications. However, since only the limited information can be observed from a single PMU, the accuracy of this measurement-based approach is restricted.

Recognizing the need of combining measurements from different locations, several methods have been proposed that rely on PMUs gathered at more locations through the reliable communication network. In recent years, the concept of “coupled single port” has been proposed for representing equivalent Thevenin parameters from wide-area measurements. This concept is to decouple a mesh network into individual equivalent Thevenin single-port circuit coupled with an extra impedance for voltage stability monitoring. The measurements collected at each load bus are used to obtain the modified Thevenin equivalent circuit with additional coupled impedances (or called virtual impedances). The VSI at each load bus can be calculated by its corresponding Thevenin equivalent circuit. Under a proportional-increase load scenario, VSI at each load bus can be obtained by individual Thevenin equivalent circuit. Unfortunately, we have observed that the existing coupled single-port model may provide under-estimations if loads are not proportionally increasing in simulation studies of IEEE test systems.

Modeling the coupling term as an extra impedance in the coupled single-port circuit will still result in some imprecise voltage instability estimations. This inaccuracy comes from the invalid assumption of the constant voltage ratio VLi/VLj and the constant coupled impedance Z_{coupled,i.} For an illustration purpose, the coupled single-port model has been investigated for the IEEE 14-bus system which is shown in FIG. 1. It is assumed that all eight loads are uniformly increasing. FIG. 2 illustrates the voltage ratio VLi/VL1 of different load numbers of the coupled single-port model shown in FIG. 1. Variations of couple impedance Z_{coupled,i} are depicted in FIG. 3. The equivalent impedance Z_{eq,i} at each equivalent circuit can also be estimated by using two consecutive real-time PMU measurements at all load buses. The maximal loading parameter of each single-port circuit by the current coupled single-port model is shown in FIG. 4. Among all eight loads, the 5th load bus is identified as the critical load bus due to its largest voltage variations. This implies the maximal loading parameter of the 5th equivalent branch is the smallest one among all branch loading parameters, and its value can be used to represent the maximal loading parameter of the whole system. Comparisons studies of P-V curves obtained by CPFLOW and the coupled single-port model are also conducted at the critical load. As results shown in FIG. 5, the maximal loading parameter at the 5th equivalent branch represents λ*sys=0.71 while the maximal loading parameter from CPFLOW is λ*=1.363.

As a result, the couple impedance Z_{coupled,i} should be adjusted, in order to provide more accurate estimate result of voltage stability. And it seems to become a challenge in this field.

### SUMMARY

One of the purposes of the invention is to disclose a method for estimating voltage stability, includes establishing a existing multi-port equivalent model and a measurement-based equivalent impedance; calculating a reactive power response factor of a power system through two consecutive samples from a measurement system; finding a mitigation factor based on the equivalent impedance and the reactive power response factor; constructing a modified coupled single-port model with the modified impedance and voltage; and processing the voltage stability assessment according to the maximal loading parameters of the modified coupled single-port model.

### BRIEF DESCRIPTION OF THE DRAWINGS

Features and advantages of embodiments of the subject matter will become apparent as the following detailed description proceeds, and upon reference to the drawings, wherein like numerals depict like parts, and in which:

FIG. 1 illustrates a coupled single-port model investigated for the IEEE 14-bus system.

FIG. 2 illustrates the voltage ratio V_{Li}/V_{L1} of different load numbers of the coupled single-port model shown in FIG. 1.

FIG. 3 illustrates the variation of couple impedance Z_{coupled,i} of the coupled single-port model shown in FIG. 1.

FIG. 4 illustrates a prediction of maximal loading parameters on the existing coupled single-port model in IEEE-14 system.

FIG. 5 illustrates P-V curves obtained form CPFLOW and the existing coupled single-port model at the critical load.

FIG. 6 illustrates a diagram of the equivalent circuit in accordance with an embodiment of the present invention.

FIG. 7 illustrates a reactive power response factors at all loads in a power system in accordance with an embodiment for the present invention.

FIG. 8 illustrates an equivalent circuit in accordance with an embodiment of the present invention.

FIG. 9 illustrates the ith modified coupled single-port equivalent circuit in accordance with an embodiment of the present invention.

FIG. 10 illustrates calculation results of adding a correction factor of the estimation results with continuous flow (CPFLOW) in accordance with an embodiment of the present invention.

FIG. 11 illustrates flows of the method for estimating the voltage stability in accordance with an embodiment of the present invention.

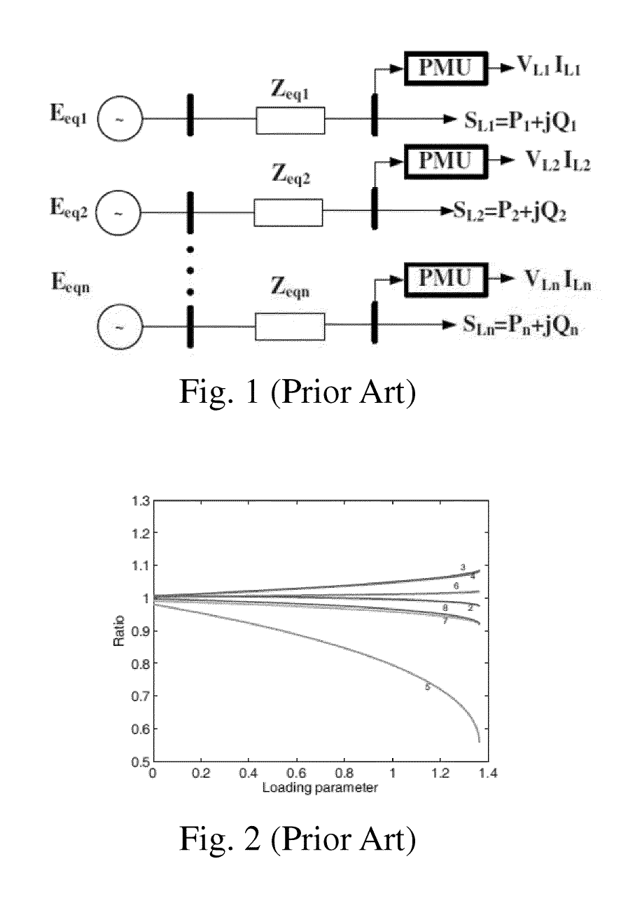

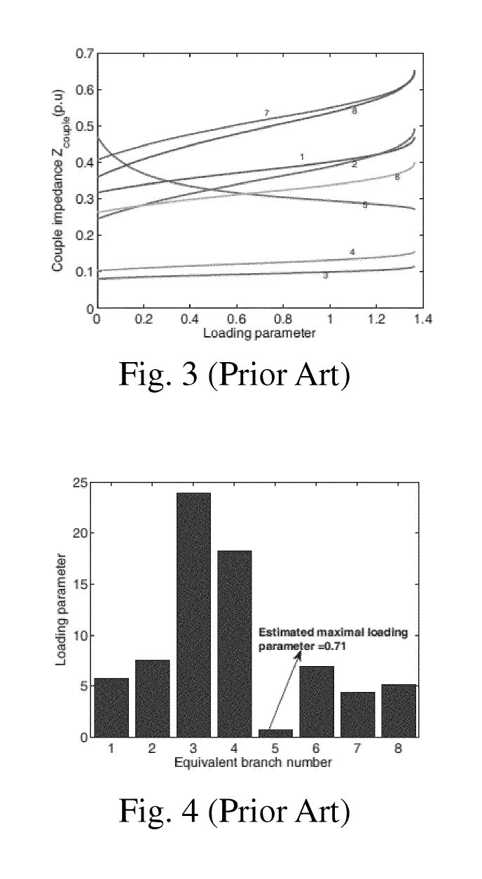

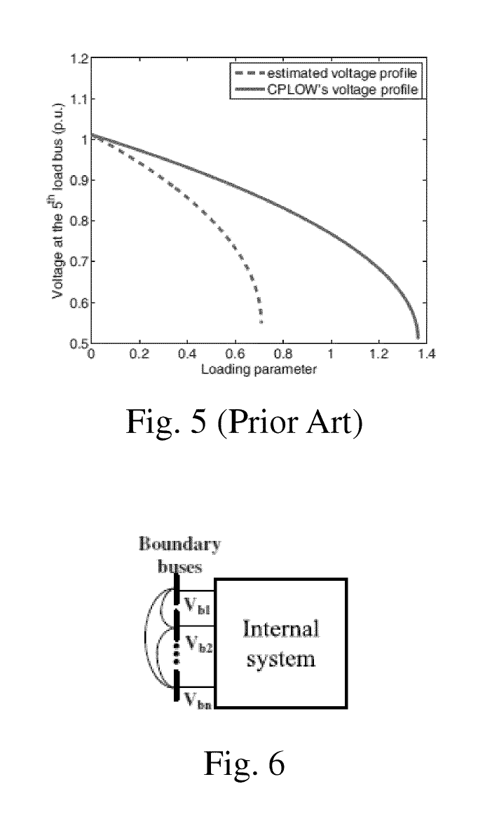

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

FIG. 6 illustrates a diagram of the equivalent circuit in accordance with an embodiment of the present invention. In FIG. 6, the only one boundary bus is considered. The external system is represented by the coupled single-port model while the internal system is represented by the local load model. The voltage at the ith boundary bus denotes V_{bi} with i=1, 2, 3, . . . n. Theoretical developments can be interpreted by the following incremental decoupled power flow:

$$\begin{matrix}{B}_{w} [ \begin{matrix}Δ \vert {V}_{b} \vert \\ Δ \vert {V}_{t} \vert\end{matrix} ] = [ \begin{matrix}{B}_{w}^{′} {B}_{bt}^{′} \\ {B}_{tb}^{′} {B}_{tt}^{′}\end{matrix} ] [ \begin{matrix}Δ \vert {V}_{b} \vert \\ Δ \vert {V}_{t} \vert\end{matrix} ] \\ = [ \begin{matrix}\frac{Δ {Q}_{b}}{\vert {V}_{b} \vert} \\ \frac{Δ {Q}_{t}}{\vert {V}_{t} \vert}\end{matrix} ]\end{matrix} \qquad ( 1 )$$

Where B_{w} matrix is derived from the network admittance matrix Y=G+jB. Y_{b} and Vₜ represent the voltage at the boundary buses and the internal system respectively. The deviation of the voltage magnitude at all boundary buses denotes Δ|V_{b}|, and the deviation of the voltage magnitude at the internal system denotes Δ|Vₜ|. The deviation of the reactive power at all boundary buses denotes ΔQ_{b}, and the deviation of the reactive power at the internal system denotes ΔQₜ.

From (1), it can be easily seen that the reactive power response with respect to the voltage deviation at boundary buses Δ|V_{b}| can be approximately expressed as:

ΔQ_{wb}=|V_{b}|B′wΔ|V_{b}| (2)

In the above expressions, the reactive power variation ΔQ_{wb}, the bus voltage V_{b}, and the bus voltage variation Δ|V_{b}| are all available if two consecutive samples can be measured at the local load bus. Thus, B′_{w}, can be estimated by the following formula:

$${B}_{w}^{′} = \frac{Δ {Q}_{wb}}{\vert {V}_{b} \vert Δ \vert {V}_{b} \vert} \qquad ( 3 )$$

The term B′_{w} obtained from the measurement approach is defined as the reactive power response factor (RPRF). It represents the normalized ratio of the reactive power response AQ,b at boundary buses with respect to the voltage deviation Δ|V_{b}| at boundary buses.

As mentioned above, poor approximations in the coupled single-port model reveals that its B′_{w} used in the analytical expression (2) is different from the one obtained from real-time PMU measurements. In order to minimize such mismatch, appending an additional reactive power support in the coupled single-port model is necessary such that its reactive power response at all local load buses is close to that obtained from PMU measurements. The additional reactive power support is conceptually represented by inserting shunt susceptance at each boundary bus.

In order to ensure accurate estimations for VSA, the existing multi-port model can be modified by considering the reactive power response of the entire power grid. Since PMUs are installed in individual load bus, load variations will be gathered through the wide-area measurement system. The RPRF of each load bus can be collected in a real-time fashion. If the RPRF of each equivalent circuit is close to that generated by the wide-area power system model, the mismatch of the voltage profile between the whole power system and the equivalent branch circuit will be diminished.

Since two consecutive PMU measurements from the ith load bus are available, the direction of the load variation γᵢ(k) at the ith equivalent circuit for a time k can be expressed by:

$${γ}_{i} ( k ) = \frac{Δ {P}_{i}}{Δ {Q}_{i}} = \frac{{P}_{i} ( k ) - {P}_{i} ( k - 1 )}{{Q}_{i} ( k ) - {Q}_{i} ( k - 1 )} \qquad ( 4 )$$

The relationship between the reactive power variation ΔQᵢ and the load bus voltage variation Δ|V_{Li}| can be established by:

ΔPᵢ=γᵢ(k)ΔQᵢ (5)

2|Z_{eq,i}|²|V_{Li}|²(2|V_{Li}|Δ|V_{Li}|+X_{eq,i}ΔQᵢ+R_{eq,i}γᵢ(k)ΔQᵢ)+2|V_{Li}|Δ|V_{Li}|Z_{eq,i}|²(2PᵢR_{eq,i}+2QᵢX_{eq,i}−|E_{eq,i}|²) +2ΔQᵢ|Z_{eq,i}|⁴(Pᵢγᵢ(k)+ΔQᵢ)=0 (6)

Now the RPRF of the ith equivalent branch BF_{eq,i}(k) is denoted by:

$${BF}_{eq , i} ( k ) = \frac{Δ {Q}_{i}}{\vert {V}_{Li} \vert Δ \vert {V}_{Li} \vert} \qquad ( 7 )$$

By replacing (6) into (7), BF_{eq,i}(k) can be written as the following expression:

$${BF}_{eq , i} ( k ) = \frac{{\vert {Z}_{eq , i} \vert}^{2} ( {\vert {E}_{eq , i} \vert}^{2} - 2 {P}_{i} {R}_{eq , i} - 2 {Q}_{i} {X}_{eq , i} - 2 {\vert {V}_{Li} \vert}^{2} )}{{\vert {Z}_{eq , i} \vert}^{4} ( {P}_{i} {γ}_{i} ( k ) + {Q}_{i} ) + {\vert {V}_{Li} \vert}^{2} {\vert {Z}_{eq , i} \vert}^{2} ( {R}_{eq , i} {γ}_{i} ( k ) + {X}_{eq , i} )} \qquad ( 8 )$$

On the other hand, the RPRF of the wide-area system BF_{system,i}(k) at the ith load can be directly calculated from two consecutive samples of PMU measurements such that BFsystem,i(k) can be expressed as:

$${BF}_{system , i} ( k ) = \frac{{Q}_{i} ( k + 1 ) - {Q}_{i} ( k )}{( {V}_{Li} ( k + 1 ) - {V}_{Li} ( k ) ) {V}_{Li} ( k )} \qquad ( 9 )$$

Since BF_{system}(k) is calculated from PMU samples, it will vary significantly. As the system loading parameter λ increases, it will approach zero.

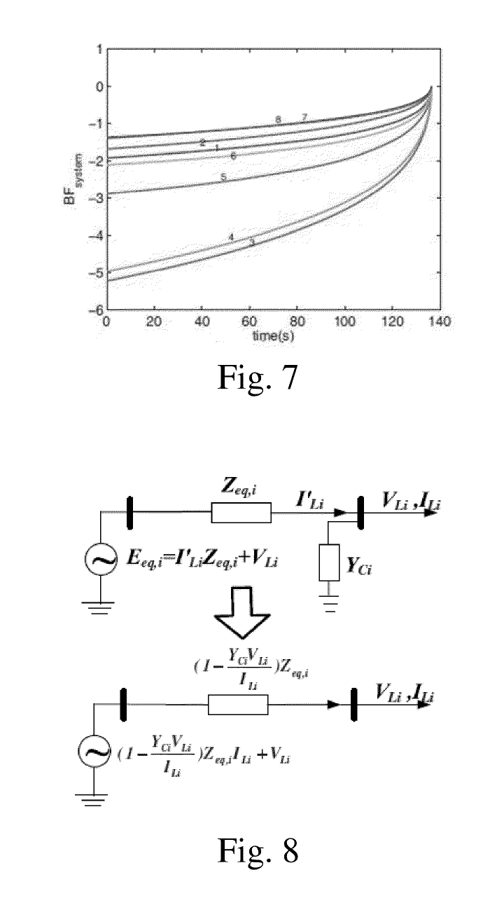

Simulations of BF_{system}(ₖ) in IEEE 14-bus system, shown in FIG. 7, can ascertain this observation.

As mentioned earlier, the voltage profile obtained by the existing coupled single-port model always provides underestimated results. This implies that BF_{system,i}(k) is larger than BF_{eq,i}(k). Consequently, the equivalent impedance Z_{eq,i} is larger than the measurement value. It is necessary to reduce the equivalent impedance Z_{eq,i} for more accurate VSA.

As depicted in FIG. 8, an additional shunt admittance should be appended into the existing equivalent branch for providing more reactive power support. To be more specific, let the shunt compensation admittance Y_{Ci} be connected to its load bus. The bus voltage V_{Li} will become:

V_{Li}=E_{eq,i}−Z_{eq,i}I′_{Li} (10)

E_{eq,i}=Z_{eq,i}I′_{Li}+V_{Li} (11)

The reduced load current I_{L} is expressed by:

$${I}_{Li}^{′} = {I}_{Li} - {Y}_{Ci} {V}_{Li} = ( 1 - \frac{{Y}_{Ci} {V}_{Li}}{{I}_{Li}} ) {I}_{Li} \qquad ( 12 )$$

By combining (20) and (21), the load bus voltage V_{Li} can be written as:

V_{Li}=(αᵢZ_{eq,i}I_{Li}+V_{Li})−αZ_{eq,i}I_{Li} (13)

Wherein, the mitigation factor αᵢ is defined by:

$${α}_{i} = 1 - \frac{{Y}_{Ci} {V}_{Li}}{{I}_{Li}} \qquad ( 14 )$$

Thus, the shunt compensation can be transformed into the series compensation by multiplying a mitigation factor αᵢ in the equivalent impedance Z_{eq,i}. It can be accomplished by letting the RPRF of each modified equivalent circuit be identical to that obtained from wide-area measurements. That is,

BF′_{eq,i}(k)=BF_{system,i}(k) (15)

Wherein, BF_{eq,i}(k) is the RPRF of the modified coupled single-port equivalent circuit with the mitigation factor αᵢ. In order to reduce the equivalent impedance, the mitigation factor αᵢ will be limited within the range 0<αᵢ<1. The load voltage V_{Li} of the ith modified coupled single-port equivalent branch circuit can be modified as:

V_{Li}=E′_{eq,i}−Z′_{eq,i}I_{Li} (16)

E′_{eq,i}=αᵢZ_{eq,i}I_{Li}+V_{Li} Z′_{eq,i}=αᵢZ_{eq,i} (17)

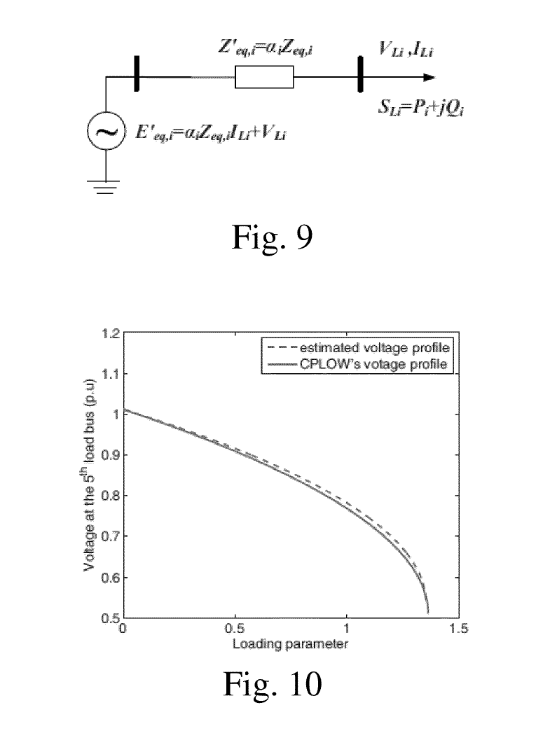

FIG. 9 depicts the ith modified coupled single-port equivalent circuit. Now the RPRF of the modified circuit BF_{eq,i} can be obtained from (18) by replacing the ith equivalent impedance with Z_{eq,i}. By separating the real part and the imaginary part, the ith modified equivalent voltage E_{eq,i} can be written as:

$$\begin{matrix}{E}_{eq , i}^{′} = {V}_{Li} + {Z}_{eq , i}^{′} {I}_{Li} \\ = {V}_{Li} + {α}_{i} {V}_{Line , i} \\ = ( {V}_{LRi} + j {V}_{LMi} ) + {α}_{i} ( {V}_{Ri} + j {V}_{Mi} )\end{matrix} \qquad ( 18 )$$

where V_{Li}=V_{LR}i+jV_{LMi} and V_{Line,i}=V_{Ri}+jV_{Mi}. If we replace the equations (8) and (18) into the equation (15), αᵢ can obtained by solving the following quadratic equation:

aαᵢ²+bαᵢ+c=0 (19)

Wherein, the coefficients a, b, and c can be written by:

a=BF_{system,i}(k)|Z_{eq,i}|²(Pᵢγᵢ(k)+Qᵢ)−|V_{Line,i}|²<0

b=BF_{system,i}(k))X_{eq,i}|V_{Li}|+R_{eq,i}|V_{Li}|²γᵢ(k)) −2V_{Ri}V_{LRi}−2V_{Mi}V_{LMi}+2PᵢR_{eq,i}+2QᵢX_{eq,i}<0

c=2|V_{Li}|−|V_{Li}|²>0

Since the formula in (19) is a quadratic function of a the solution a, at the ith equivalent branch can be calculated as:

αᵢ=(−b−\sqrt{b²−4 ac})/2a

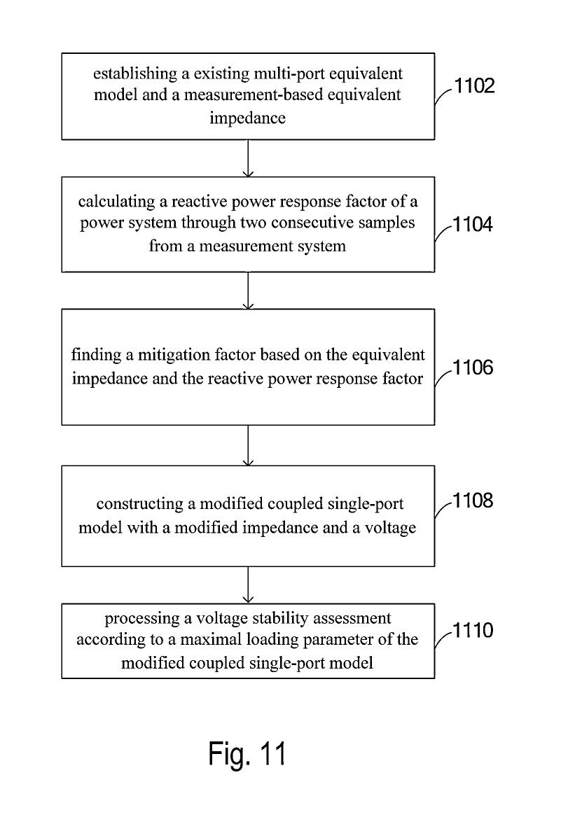

FIG. 10 illustrates calculation results of adding a mitigation factor of the estimation results with continuous flow (CPFLOW) in accordance with an embodiment of the present invention. As shown in FIG. 10, after adding the mitigation factor, the mismatch between the actual result and the estimated results can be reduced, and thus, the estimation accuracy of voltage stability can be improved significantly.

FIG. 11 illustrates flows of the method for estimating the voltage stability in accordance with an embodiment of the present invention. In block 1102, establishing the existing multi-port equivalent model and the measurement-based equivalent impedance Z_{eq,i}. In block 1104, calculating a reactive power response factor BF_{system,i} through two consecutive samples from wide-area PMU measurements. In block 1106, finding the mitigation factor αᵢ based on the equivalent impedance Z_{eq,i} and the BF_{system,i.} In block 1108, constructing the modified coupled single-port model with the modified impedance Z_{eq,i} and voltage E_{eq,i}. In block 1110, process the voltage stability assessment according to the modified maximal loading parameter.

While the foregoing description and drawings represent embodiments of the present invention, it will be understood that various additions, modifications and substitutions may be made therein without departing from the spirit and scope of the principles of the present invention. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, and not limited to the foregoing description.

What is claimed is:

1. A method for estimating voltage stability, comprising:
establishing a existing multi-port equivalent model and a measurement-based equivalent impedance;
calculating a reactive power response factor of a power system through two consecutive samples from a measurement system;
finding a mitigation factor based on the equivalent impedance and the reactive power response factor;
constructing a modified coupled single-port model with the modified impedance and voltage; and
processing voltage stability assessment according to a maximal loading parameter of the modified coupled single-port model.

2. The method as claimed in claim 1, wherein the measurement system includes a phasor measurement unit.

3. The method as claimed in claim 1, wherein the reactive power response factor of the power system is calculated by
$${BF}_{system , i} ( k ) = \frac{{Q}_{i} ( k + 1 ) - {Q}_{i} ( k )}{( {V}_{Li} ( k + 1 ) - {V}_{Li} ( k ) ) {V}_{Li} ( k )} .$$

4. The method as claimed in claim 1, wherein the mitigation factor is calculated
$$by {α}_{i} = 1 - \frac{{Y}_{Ci} {V}_{Li}}{{I}_{Li}} ,$$
and wherein, αᵢ indicates the mitigation factor, Y_{Ci} indicates a compensation admittance, V_{Li} indicates a voltage of a load bus, and I_{Li} indicates a current of the load bus.

5. The method as claimed in claim 1, wherein the mitigation factor is calculated by aαᵢ²+bαᵢ+c=0 .

6. The method as claimed in claim 5, further comprising:
calculating coefficients a, b, and c of the mitigation factor by the equations of
a=BF_{system,i}(k)|Z_{eq,i}|²(Pᵢγᵢ(k)+Qᵢ)−|V_{Line,i}|²<0
b=BF_{system,i}(k))X_{eq,i}|V_{Li}|+R_{eq,i}|V_{Li}|²γᵢ(k)) −2V_{Ri}V_{LRi}−2V_{Mi}V_{LMi}+2PᵢR_{eq,i}+2QᵢX_{eq,i}<0
c=2|V_{Li}|−|V_{Li}|²>0

7. The method as claimed in claim 1, wherein the value of the mitigation factor is between 0 and 1.
